(19) United States
(12) Patent Application Publication
(10) Pub. No.: US 2008/0057736 A1
(43) Pub. Date: Mar. 6, 2008

(54) METHOD FOR IMPROVING ADHESION FORCE BETWEEN THIN FILMS

(75) Inventor: Tae Young Lee, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/846,639

(22) Filed: Aug. 29, 2007

(30) Foreign Application Priority Data
Aug. 30, 2006 (KR) 10-2006-0083183

(51) Int. Cl. H01L 21/31

(52) U.S. Cl. 438/763; 257/E21.24

(57) ABSTRACT

Methods for improving an adhesive force between thin films of a semiconductor device. In one example embodiment, a method for improving an adhesive force between an HDP-CVD (High Density Plasma-Chemical Vapor Deposition) thin film and a nitride film includes forming a HDP-CVD thin film according to an HDP-CVD method in order to exert a compressive stress against a lower structure, and forming a nitride film on the HDP-CVD thin film that exerts a tensile stress that substantially cancels out the compressive stress.

### CROSS-REFERENCE TO RELATED APPLICATION

This application claims priority to Korean Application No. 10-2006-0083183, filed on Aug. 30, 2006, which is incorporated herein by reference in its entirety.

### BACKGROUND

1. Field of the Invention

The invention relates to improving an adhesion force between thin films of a semiconductor device.

2. Description of the Related Art

With the advancement of semiconductor device fabrication technologies, it has become possible to produce semiconductor devices having increasingly finer structures. In general, semiconductor devices include multiple thin films adhered to one another. The adhesion force between the thin films of a semiconductor device is one of the factors that influences whether the device possesses favorable operational characteristics. For example, if the adhesion force between thin films is weak, the thin films might separate from each other, thereby degrading the operational characteristics of the semiconductor device.

FIGS. 1 and 2 disclose a bending phenomenon of prior art thin films. As disclosed in FIGS. 1 and 2, when a second thin film 2 is formed on a first thin film 1, stress may be generated due to a difference in thermal expansion coefficients between the first and second thin films 1 and 2. More particularly, a tensile stress or a compressive stress may be generated due to a difference in thermal expansion coefficients between the first and second thin films 1 and 2. For example, if the thermal expansion coefficient of the second thin film 2 is greater than that of the first thin film 1, the first and second thin films 1 and 2 may be bent in the direction of the arrows shown in FIG. 1. Conversely, if the thermal expansion coefficient of the second thin film 2 is less than that of the first thin film 1, the first and second thin films 1 and 2 may be bent in the direction of the arrows shown in FIG. 2.

As a result of the stress and bending of the first thin film 1 and/or the second thin film 2, cracks, voids, or other types of damage may appear in the first and/or second thin films 1 and 2. This damage can result in unfavorable operational characteristics in the semiconductor device.

### SUMMARY OF EXAMPLE EMBODIMENTS

In general, example embodiments of the invention relate to improving an adhesion force between thin films of a semiconductor device. This improvement in the adhesion force can be accomplished by managing the stress between the thin films.

In one example embodiment, a method for improving an adhesive force between an HDP-CVD (High Density Plasma-Chemical Vapor Deposition) thin film and a nitride film includes forming a HDP-CVD thin film according to an HDP-CVD method in order to exert a compressive stress against a lower structure. The example method also includes forming a nitride film on the HDP-CVD thin film that exerts a tensile stress that substantially cancels out the compressive stress.

In another example embodiment, a method for improving an adhesion force between a liner film and an HDP-FSG (High Density Plasma-Fluorinated Silica Glass) thin film includes forming a liner film that covers a metal wiring, the liner film being formed between about 260° C. and about 360° C. in order to exert a compressive stress against a lower structure. The example method also includes forming an HDP-FSG thin film on the liner film that exerts a tensile stress that substantially cancels out the compressive stress.

In still another example embodiment, a method for improving an adhesive force of an insulation layer includes forming at least two insulation layers and at least one metal wiring. The insulation layers and the metal wiring(s) are alternately disposed. The method also includes forming an upper insulation layer that exerts a compressive stress on the at least two insulation layers and that causes the at least two insulation layers to remain substantially connected to the at least one metal wiring.

In yet another example embodiment, a method for improving an adhesion force between thin films includes forming a metal wiring. The example method also includes forming an interlayer insulation film on the metal wiring according to an HDP-CVD method. The example method further includes forming a TEOS (Tetraethoxysilane) film on the interlayer insulation film according to a PECVD (Plasma Enhanced Chemical Vapor Deposition) method in order to improve an adhesion force with respect to the interlayer insulation film by being chemically Si—OH combined with the interlayer insulation film.

### BRIEF DESCRIPTION OF THE DRAWINGS

Aspects of example embodiments of the invention will become apparent from the following description of example embodiments given in conjunction with the accompanying drawings, in which:

FIGS. 1 and 2 are sectional views showing prior art bent thin films;

FIG. 3 is a sectional view showing an example method for improving an adhesion force between thin films;

FIG. 4 is a sectional view showing a second example method for improving an adhesion force between thin films;

FIG. 5 is a sectional view showing a third example method for improving an adhesion force between thin films; and

FIG. 6 is a sectional view showing a fourth example method for improving an adhesion force between thin films.

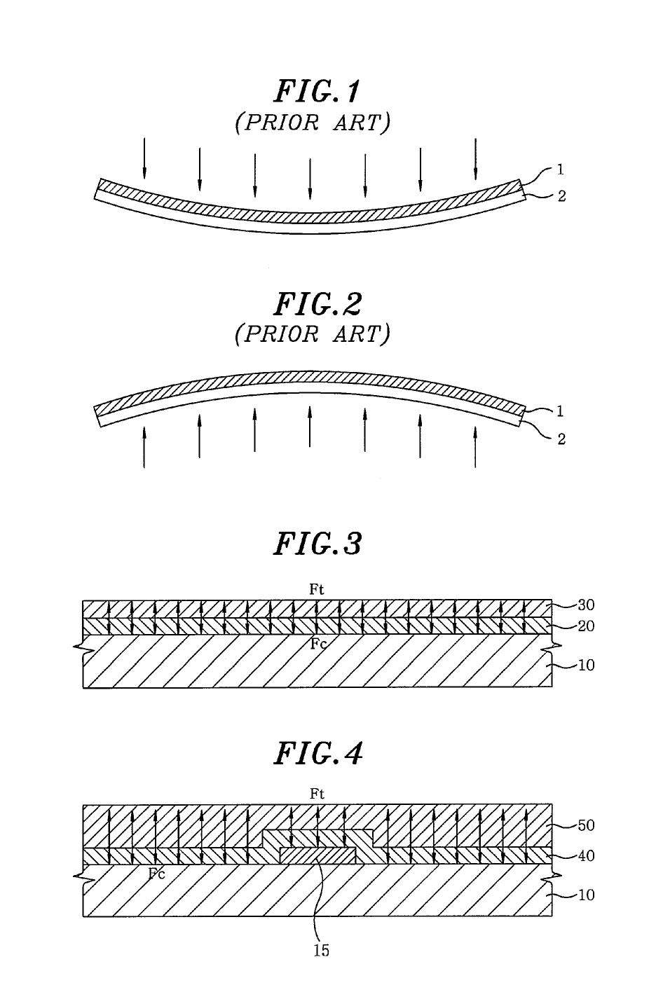

### DETAILED DESCRIPTION OF EXAMPLE EMBODIMENTS

Hereinafter, example methods for improving an adhesion force between thin films will be described in detail with reference to the accompanying drawings.

FIG. 3 discloses a first example method for improving an adhesion force between thin films. As disclosed in FIG. 3, an HDP-CVD (High Density Plasma-Chemical Vapor Deposition) thin film 20 is formed on an upper surface of a substrate 10. The substrate 10 may be formed from various materials including, but not limited to, silicon. The substrate 10 may be formed at a temperature between about 260° C. and about 360° C. according to an HDP-CVD method. The thin film 20 exerts a compressive stress (Fc) against the substrate 10. A nitride film 30 is formed on the thin film 20. The nitride film 30 exerts a tensile stress (Ft) against the thin film 20. The tensile stress (Ft) substantially cancels out the compressive stress (Fc).

In this first example method, the strength of the compressive stress (Fc) of the HDP-CVD thin film 20 is proportional to the temperature at which the HDP-CVD thin film 20 is formed (hereinafter referred to as the “processing temperature” of the HDP-CVD thin film 20). For example, if the processing temperature of the HDP-CVD thin film 20 is lower than about 260° C., the compressive stress (Fc) of the HDP-CVD thin film 20 becomes substantially weaker than the tensile stress (Ft) of the nitride film 30. This difference in stress strengths between the HDP-CVD thin film 20 and the nitride film 30 can cause the nitride film 30 to separate from the HDP-CVD thin film 20.

Similarly, if the processing temperature of the HDP-CVD thin film 20 is higher than about 360° C., the compressive stress (Fc) of the HDP-CVD thin film 20 becomes substantially greater than the tensile stress (Ft) of the nitride film 30. This difference in stress strengths between the HDP-CVD thin film 20 and the nitride film 30 can likewise cause the nitride film 30 to separate from the HDP-CVD thin film 20.

To avoid these undesirable results, the HDP-CVD thin film 20 in this first example method can be formed between about 260° C. and about 360°. Thus formed, the compressive stress (Fc) of the HDP-CVD thin film 20 cancels out the tensile stress (Ft) of the nitride film 30, resulting in an improvement of adhesion force between the HDP-CVD thin film 20 and the nitride film 30.

FIG. 4 discloses a second example method for improving an adhesion force between thin films. As disclosed in FIG. 4, a metal wiring 15 is formed on a substrate 10. The substrate 10 may be formed from various materials including, but not limited to, silicon. A liner film 40 is formed on the metal wiring 15, and an HDP-FSG (High Density Plasma-Fluorinated Silica Glass) film 50 is formed on the liner film 40 according to an HDP-CVD process.

The liner film 40 serves as an ion-blocking film that prevents fluorine (F) contained in the HDP-FSG film 50 from infiltrating into the metal wiring 15. In this second example method, the liner film 40 is formed between about 260° C. and about 360°. The liner film 40 exerts a compressive stress (Fc) against the substrate 10. The HDP-FSG film 50 exerts a tensile stress (Ft) that cancels out the compressive stress (Fc), thus improving an adhesion force between the liner film 40 and the HDP-FSG film 50.

In this second example method, the strength of the compressive stress (Fc) of the liner film 40 is proportional to the processing temperature of the liner film 40. For example, if the processing temperature of the liner film 40 is lower than about 260° C., the compressive stress (Fc) of the liner film 40 becomes substantially weaker than the tensile stress (Ft) of the HDP-FSG film 50. This difference in stress strengths between the liner film 40 and HDP-CVD film 50 can cause the liner film 40 to separate from the HDP-FSG film 50.

Similarly, if the processing temperature of the liner film 40 is higher than about 360° C., the compressive stress (Fc) of the liner film 40 becomes substantially greater than the tensile stress (Ft) of the HDP-FSG film 50. This difference in stress strengths between the liner film 40 and the HDP-FSG film 50 can cause the liner film 40 to separate from the HDP-FSG film 50.

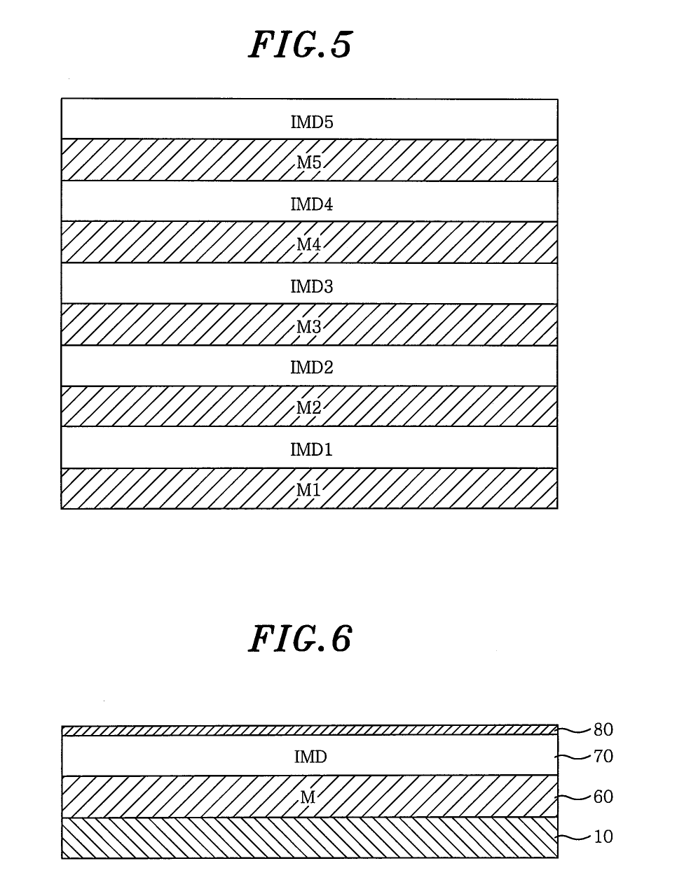

FIG. 5 discloses a third example method for improving an adhesion force between thin films. The thin films of the semiconductor device disclosed in FIG. 5 include multiple metal wirings. In particular, as shown in FIG. 5, metal wirings M2, M3, M4, and M5 are alternately disposed between interlayer insulation films IMD1, IMD2, IMD3, IMD4, and IMD5. In addition, a metal wiring (M1) is disposed below the interlayer insulation film IMD1.

As disclosed in FIG. 5, the interlayer insulation films IMD2 is disposed adjacent to the metal wiring M3. In order to prevent the separation of the interlayer insulation film IMD2 from the metal wiring M3, the upper interlayer insulation film IMD4 or IMD5 can be formed between about 260° C. and about 360° C. Forming the upper interlayer insulation film IMD4 or IMD5 in this temperature range can improve a compressive stress of the upper interlayer insulation film IMD4 or IMD5 to thus prevent the interlayer insulation film IMD2 from being separated.

FIG. 6 disclosed a fourth example method for improving an adhesion force between thin films. As disclosed in FIG. 6, a metal wiring 60 is formed on the upper surface of a substrate 10. The substrate 10 may be formed from various materials including, but not limited to, silicon. An interlayer insulation film 70 is formed on the metal wiring according to an HDP-CVD method, and a PETEOS (Plasma Enhanced Tetraethylorthosilicate) film 80 is formed on the interlayer insulation film 70 according to a PECVD (Plasma Enhanced Chemical Vapor Deposition) method.

In this fourth example method, the PETEOS film 80 can alternatively include, or be replaced with, a cap silane (SiH4) film. The interlayer insulation film 70 and the PETEOS film can be chemically silanol (Si—OH) combined with each other. The interlayer insulation film 70 and cap silane film can also be chemically Si—H combined with each other. In this fourth example method, the combination of the interlayer insulation film 70 and the PETEOS film 80 has an Si—O—H bonding structure. Since the coherence of silicon-oxygen-hydrogen is better than that of silicon-hydrogen, the adhesion force between the interlayer insulation film 70 and the PETEOS film 80 being greater than the coherence between the interlayer insulation film 70 and the cap silane film.

Accordingly, after the metal wiring 60 is formed on the substrate 10 and the interlayer insulation film 70 is formed to cover the metal wiring 60 according to an HDP-CVD method, the PETEOS film 80, instead of the cap silane film, can be formed to improve the adhesion force between the interlayer insulation film 70 and the PETEOS film 80.

As described above, the adhesion force between the thin films can be improved by controlling the processing temperature of thin films to minimize stress generated between the thin films or by using the thin film which is chemically OH-combined with silicon included in the thin film.

While the invention has been shown and described with respect to some example embodiments, it will be understood by those skilled in the art that various changes and modifications may be made without departing from the scope of the invention as defined in the following claims.

What is claimed is:

1. A method for improving an adhesive force between an HDP-CVD thin film and a nitride film, the method comprising:
forming an HDP-CVD thin film according to an HDP-CVD method in order to exert a compressive stress against a lower structure; and
forming a nitride film on the HDP-CVD thin film that exerts a tensile stress that substantially cancels out the compressive stress.

2. The method of claim 1, wherein the HDP-CVD thin film is formed between about 260° C. and about 360° C.

3. A method for improving an adhesion force between a liner film and an HDP-FSG thin film, the method comprising:
forming a liner film that covers a metal wiring and that exerts a compressive stress against a lower structure; and
forming a HDP-FSG thin film on the liner film that exerts a tensile stress that substantially cancels out the compressive stress.

4. The method of claim 3, wherein the liner film is formed between about 260° C. and about 360° C.

5. The method of claim 3, wherein, during the forming of the liner film, the lower structure is heated between about 260° C. and about 360° C. for between about 30 seconds and about 60 seconds.

6. A method for improving an adhesive force of an insulation layer, the method comprising:
forming at least two insulation layers and at least one metal wiring, wherein the insulation layers and the metal wiring(s) are alternately disposed; and
forming an upper insulation layer that exerts a compressive stress on the at least two insulation layers and that causes the at least two insulation layers to remain substantially connected to the at least one metal wiring.

7. The method of claim 6, wherein the upper insulation layer is formed between about 260° C. and about 360° C.
